(19) United States
(12) Patent Application Publication
(10) Pub. No.: US 2009/0289378 A1
(43) Pub. Date: Nov. 26, 2009

(54) SEMICONDUCTOR WAFER

(75) Inventor: Tomohiro HASHII, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/467,438

(22) Filed: May 18, 2009

(30) Foreign Application Priority Data
May 21, 2008 (JP) 2008-133078

(51) Int. Cl. H01L 23/544

(52) U.S. Cl. 257/797; 257/E23.002

(57) ABSTRACT

The present invention is a semiconductor wafer including an orientation identification mark, which is used for identifying crystal orientation, on a peripheral surface thereof, in which the orientation identification mark is smoothly joined with a portion outside of the orientation identification mark on the peripheral surface, has a planar surface that is orthogonal to an inner diameter direction of the semiconductor wafer, and has a gloss different from that in the portion outside of the orientation identification mark on the peripheral surface.

This application is based on and claims the benefit of priority from Japanese Patent Application No. 2008-133078, filed on 21 May 2008, the content of which is incorporated herein by reference.

### BACKGROUND OF THE INVENTION

1. Field of the Invention

The present invention relates to a semiconductor wafer including an orientation identification mark for identifying crystal orientation.

2. Related Art

In a semiconductor wafer (hereinafter simply referred to as “wafer”) that is sliced from a semiconductor ingot such as a silicon ingot, an orientation identification mark for identifying crystal orientation thereof is provided on a peripheral portion thereof. The orientation identification mark is used, for example, for alignment of the wafer with respect to various processing devices. Conventionally, an orientation flat (hereinafter also referred to as “OF”), a notch, a laser mark or the like have been used as the orientation identification mark (for example, see Japanese Unexamined Patent Application Publication Nos. 2005-19579, No. 2001-160527, and No. Hei 10-256105).

However, in the wafer including the abovementioned orientation identification mark such as the OF, notch, laser mark or the like, breakage and slip may easily occur due to stress concentrated in a peripheral portion of the orientation identification mark, for example during transportation (in which the wafer bends particularly easily) and processing (particularly in a thermal process) thereof. Such a problem is considered to be more significant as the size of the wafers increases.

### SUMMARY OF THE INVENTION

An objective of the present invention is to provide a semiconductor wafer that includes an orientation identification mark for identifying crystal orientation and that can inhibit stress concentration in a peripheral portion of the orientation identification mark therein.

In a first aspect of the present invention, a semiconductor wafer includes an orientation identification mark, which is used for identifying crystal orientation, on a peripheral surface thereof, wherein the orientation identification mark: is smoothly joined with a portion outside of the orientation identification mark on the peripheral surface; has a planar surface that is orthogonal to an inner diameter direction of the semiconductor wafer; and has a gloss different from that in the portion outside of the orientation identification mark on the peripheral surface.

According to a second aspect of the present invention, in the semiconductor wafer as described in the first aspect, it is preferable that: the orientation identification mark has a rectangular shape when the semiconductor wafer is seen from the inner diameter direction; the orientation identification mark, which has a rectangular shape, has a width smaller than a perimeter of the peripheral surface of the semiconductor wafer and a height smaller than thickness of the semiconductor wafer; and the orientation identification mark is positioned more on an inner side in a thickness direction than a first surface and a second surface of the semiconductor wafer.

According to a third aspect of the present invention, in the semiconductor wafer as described in the second aspect, it is preferable that the width of the orientation identification mark, which has a rectangular shape, is in a range of 0.1 to 5.0 mm and the height is in a range of 0.3 to 1.8 mm.

According to the present invention, in a semiconductor wafer that includes an orientation identification mark for identifying crystal orientation, stress concentration in a peripheral portion of the orientation identification mark therein can be inhibited.

### BRIEF DESCRIPTION OF THE DRAWINGS

FIGS. 1A to 1D are diagrams illustrating an embodiment of a semiconductor wafer according to the present invention respectively:

FIG. 1A is a diagram illustrating the entire semiconductor wafer according to the present embodiment, seen from a thickness direction;

FIG. 1B is an enlarged view of a portion indicated by an arrow B in FIG. 1A;

FIG. 1C is a diagram illustrating the semiconductor wafer seen from a second direction D2 shown in FIG. 1B;

FIG. 1D is a diagram illustrating the semiconductor wafer seen from a first direction D1 shown in FIG. 1B; and

FIGS. 2A to 2D are diagrams (corresponding to FIG. 1C) sequentially showing steps for forming the orientation identification mark on the semiconductor wafer.

### DETAILED DESCRIPTION OF THE INVENTION

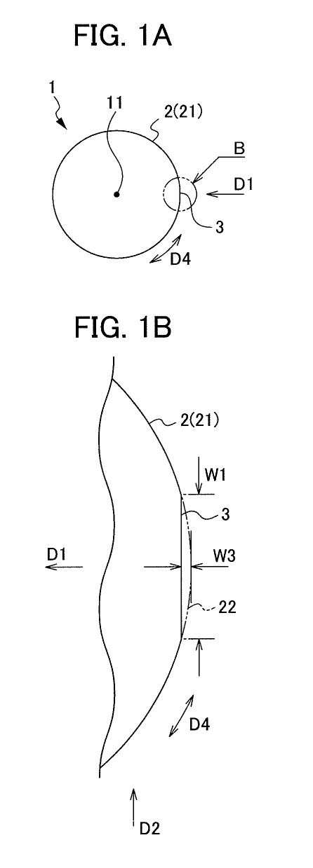

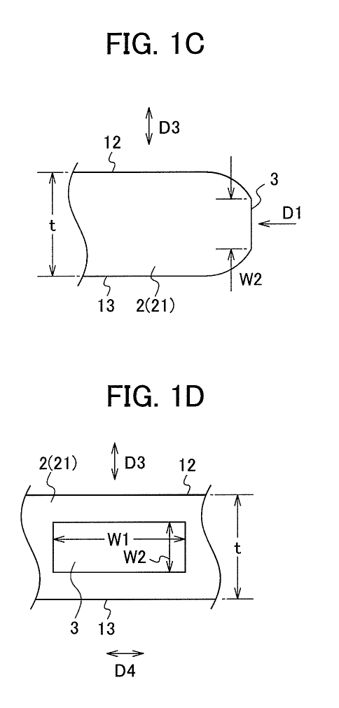

An embodiment of the semiconductor wafer (hereinafter also referred to simply as “wafer”) according to the present invention is described hereinafter with reference to the drawings. FIGS. 1A to 1D are diagrams illustrating an embodiment of a semiconductor wafer according to the present invention. FIG. 1A is a diagram illustrating the entire semiconductor wafer according to the present embodiment, seen from a thickness direction. FIG. 1B is an enlarged view of a portion indicated by an arrow B in FIG. 1A. FIG. 1C is a diagram illustrating the semiconductor wafer seen from a second direction D2 shown in FIG. 1B. FIG. 1D is a diagram illustrating the semiconductor wafer seen from a first direction D1 shown in FIG. 1B. The second direction D2 is a direction parallel to a surface direction of the orientation identification mark 3.

A wafer 1 according to the present embodiment is, for example, a silicon wafer or a gallium arsenide wafer.

As shown in FIGS. 1A to 1D, a shape of the wafer 1, in which an orientation identification mark 3 (described later) is not formed, seen from a thickness direction (a third direction D3) is typically a perfect circle. Diameter of the wafer 1 is, for example, 200 mm, 300 mm, or 450 mm. Here, the diameter of the wafer 1 is a desired value in manufacturing, and includes a predetermined tolerance (allowable margin of error). The shape of the wafer 1 seen from the thickness direction D3 can also be elliptical.

Thickness t of the wafer 1 is, for example, in a range of 725 to 2000 μm, and preferably in a range of 925 to 1800 μm.

The wafer 1 according to the present embodiment is not provided with a conventional orientation identification mark, such as an orientation flat (OF), a notch, a laser mark or the like, as an orientation identification mark that is used for identification of crystal orientation. Instead, the wafer 1 according to the present embodiment is provided with the orientation identification mark 3 on a peripheral surface 2 thereof.

The orientation identification mark 3 is a mark used for identifying crystal orientation and provided at a position indicating crystal orientation <110>±1 degree on a peripheral surface 2 of the wafer 1, for example.

The orientation identification mark 3 is smoothly joined with a portion outside of the orientation identification mark 3 (hereinafter referred to as “unmarked portion 21”) on the peripheral surface 2 and has a planar surface that is orthogonal to an inner diameter direction (first direction) D1 of the wafer 1. As used herein, “smoothly joined” indicates that the orientation identification mark 3 and the unmarked portion 21 are joined to each other with substantially no edge therebetween. The inner diameter direction D1 of the wafer 1 is a direction from the peripheral surface 2 of the wafer 1 to a center 11 of the wafer 1.

In addition, the orientation identification mark 3 has a gloss that is different from that of the unmarked portion 21. As used herein, “having a gloss that is different” indicates that the gloss is different to such a degree that the orientation identification mark 3 and the unmarked portion 21 can be distinguished by an optical sensor or can be visually distinguished.

The orientation identification mark 3 has a rectangular shape in a case where the wafer 1 is seen from the inner diameter direction D1. More specifically, the orientation identification mark 3, which has a rectangular shape, has a width W1 smaller than a perimeter of the peripheral surface 2 of the wafer 1 and a height W2 smaller than a thickness t of the wafer 1. In addition, the orientation identification mark 3, which has a rectangular shape, is positioned more on an inner side in the thickness direction D3 than a first surface 12 (one principal surface) and a second surface 13 (another principal surface) of the wafer 1.

The width W1 of the orientation identification mark 3, which has a rectangular shape, is, for example, in a range of 0.1 to 10.0 mm and preferably in a range of 0.1 to 5.0 mm. In addition, a height W2 thereof is, for example, in a range of 0.1 to 2.0 mm and preferably in a range of 0.3 to 1.8 mm.

As shown in FIG. 1B, the orientation identification mark 3 is positioned more to the inside in the inner diameter direction D1 than the peripheral surface 2 of the wafer 1 and extends in a direction that is orthogonal to a diameter direction (the first direction D1) of the wafer 1. A two-dot chain line in FIG. 1B is a virtual extended line 22 of the peripheral surface 2. A depth (maximum depth) W3 of the orientation identification line 3 from the virtual extended line 22 is, for example, in a range of 575 to 2225 μm, and more preferably in a range of 1075 to 1175 μm.

In a case where the wafer 1 is seen from the second direction D2, in the unmarked portion 21 on the peripheral surface 2 of the wafer 1, a portion closer to the first surface 12 than the orientation identification mark 3 and a portion closer to the second surface 13 than the orientation identification mark 3 are rounded.

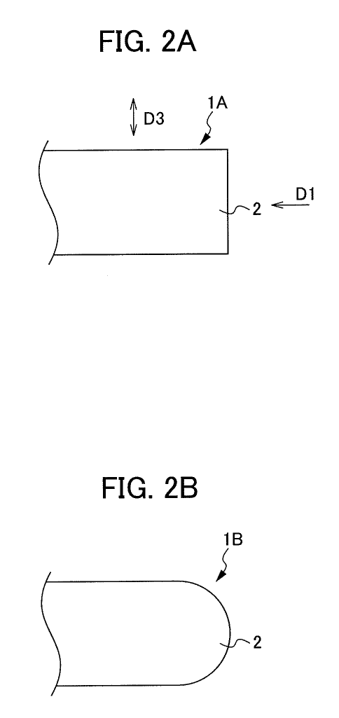

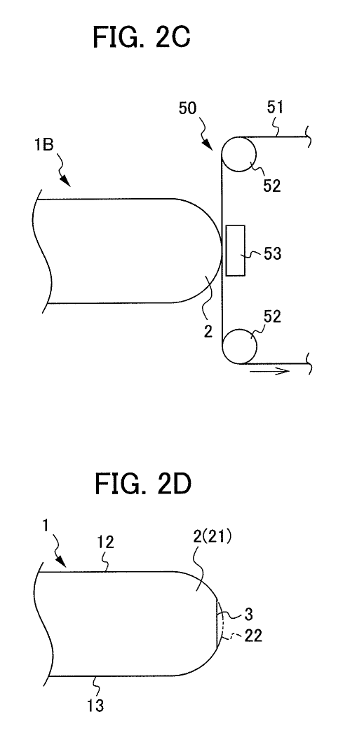

A manufacturing method for the wafer 1 according to the present embodiment is hereinafter described with reference to the drawings. FIGS. 2A to 2D are diagrams sequentially showing steps for forming the orientation identification mark on the semiconductor wafer (corresponding to FIG. 1C).

In a slicing step, a semiconductor wafer 1A as shown in FIG. 2A is obtained by slicing a semiconductor ingot (not shown) by way of a wire saw or the like. Here, the wafer 1A is not chamfered.

As shown in FIG. 2B, in a chamfering step, the wafer 1A obtained in the slicing step is subjected to chamfering processing (beveling), thus obtaining a semiconductor wafer 1B. More specifically, a grinding wheel is brought into contact with an edge on the peripheral surface 2 of the wafer 1, thereby rounding the edge. This is aimed at preventing cracking of the wafer 1 and generation of dust from the wafer 1.

As shown in FIG. 2C, in a mark-forming step, an orientation identification mark 3 is formed on the semiconductor wafer 1B obtained in the chamfering step.

The orientation identification mark 3 is formed by means of, for example, a tape chamfering device 50.

The tape chamfering device 50 includes a chamfering tape 51, a pair of guiding rollers 52, 52, a rotation motor (not shown), and a pressing member 53 made of synthetic resin.

The chamfering tape 51 is configured such that abrasive grains (synthetic diamonds and the like) are fixed with an adhesive on a polishing surface of a synthetic resin tape. The chamfering tape 51 is stretched around the pair of guiding rollers 52, 52. The rotation motor moves the chamfering tape 51 around and between the pair of guiding rollers 52, 52. A longitudinal direction of the chamfering tape 51 is the thickness direction D3 of the wafer 1B.

The pressing member 53 is disposed on a side of the chamfering tape 51 that is opposite to the polishing surface thereof and presses the chamfering tape 51, which is circulating, against the peripheral surface 2 of the wafer 1B in the inner diameter direction D1. In addition, the pressing member 53 is movable toward and away from the chamfering tape 51. Furthermore, the pressing member 53 is movable in a circumferential direction D4 (see FIGS. 1A to 1D) of the wafer 1 and/or in a direction that is orthogonal to the diameter direction (the first direction D1) of the wafer 1.

With the tape chamfering device 50 thus configured, the orientation identification mark 3 can be formed on the wafer 1B by: pressing the polishing surface of the chamfering tape 51, which is circulated by the rotation motor, against a predetermined position on the peripheral surface 2 of the wafer 1B (a position at which the orientation identification mark 3 is formed) with a predetermined pressing force in the inner diameter direction D1. Here, the chamfering tape 51 can be moved back and force in a small length, in a direction of a tangent to the peripheral surface 2 of the wafer 1B, as necessary. As a result, a part of the peripheral surface 2 of the wafer 1B is removed and a planar portion that is orthogonal to the inner diameter direction D1 of the wafer 1B is formed, which is the orientation identification mark 3.

Here, the orientation identification mark 3 has a gloss different from that in the unmarked portion 21 on the peripheral surface 2. In addition, in tape chamfering processing, processing distortions do not easily occur, thus alleviating stress concentration in a peripheral portion of the orientation identification mark 3 on the wafer 1.

It should be noted that, in addition to the abovementioned steps, various steps can be carried out before and after the mark forming step, as necessary.

As described above, in the wafer 1 according to the present embodiment, the orientation identification mark 3 is smoothly joined with a portion outside of the orientation identification mark 3 (unmarked portion 21) on the peripheral surface 2, has a planar surface that is orthogonal to the inner diameter direction D1 of the wafer 1, and has a gloss different from that in the unmarked portion 21. As a result, crystal orientation can be identified by an optical sensor or can be visually identified, and stress concentration in a peripheral portion of the orientation identification mark 3 on the wafer 1 can be inhibited.

An embodiment of the present invention has been described above; however, the present invention is not limited thereto.

For example, in the abovementioned mark forming step, although the orientation identification mark 3 is formed by means of the tape chamfering device 50 in order to inhibit processing distortions, the present invention is not limited thereto. As processing that does not easily generate processing distortions, processing such as etching, polishing, and the like can be adopted for forming the orientation identification mark 3.

What is claimed is:

1. A semiconductor wafer comprising an orientation identification mark used for identifying crystal orientation, on a peripheral surface thereof,
wherein the orientation identification mark: is smoothly joined with a portion outside of the orientation identification mark on the peripheral surface; has a planar surface that is orthogonal to an inner diameter direction of the semiconductor wafer; and has a gloss different from that in the portion outside of the orientation identification mark on the peripheral surface.

2. The semiconductor wafer according to claim 1, wherein: the orientation identification mark has a rectangular shape when the semiconductor wafer is seen from the inner diameter direction;
the orientation identification mark, which has a rectangular shape, has a width smaller than a perimeter of the peripheral surface of the semiconductor wafer and a height smaller than thickness of the semiconductor wafer;
and the orientation identification mark is positioned more on an inner side in a thickness direction than a first surface and a second surface of the semiconductor wafer.

3. The semiconductor wafer according to claim 2, wherein the width of the orientation identification mark, which has a rectangular shape, is in a range of 0.1 to 5.0 mm and the height is in a range of 0.3 to 1.8 mm.
